(19) United States
(12) Patent Application Publication
(10) Pub. No.: US 2026/0161874 A1
(43) Pub. Date: Jun. 11, 2026

(54) METHOD FOR TRANSMITTING AND RECEIVING DATA BETWEEN CHIPLETS HAVING DIFFERENT AXI PARAMETERS AND SEMICONDUCTOR PACKAGE THEREOF

(71) Applicant: OPENEDGES TECHNOLOGY, INC., Seoul (KR)

(72) Inventors: Jaekwang LEE, Seoul (KR); Hyungyu KIM, Seoul (KR)

(73) Assignee: OPENEDGES TECHNOLOGY, INC., Seoul (KR)

(21) Appl. No.: 19/378,537

(22) Filed: Nov. 4, 2025

(30) Foreign Application Priority Data
Dec. 10, 2024 (KR) 10-2024-0182400

(51) Int. Cl. G06F 30/392

(52) U.S. Cl. CPC G06F 30/392

(57) ABSTRACT

Provided, according to one embodiment of the present disclosure, is a semiconductor package comprising a plurality of chiplets, wherein: each of the plurality of chiplets is configured to operate according to AXI protocol; and the plurality of chiplets are configured to communicate with one another using UCIe protocol. A first chiplet of the plurality of chiplets comprises: a first AXI interface configured to operate based on a first AXI parameter; and a first conversion module configured to receive a packet, extract a source AXI parameter from the received packet, and convert the received packet into a target AXI signal based on the source AXI parameter and the first AXI parameter.

### CROSS-REFERENCE TO RELATED APPLICATIONS

This application claims priority to Korean Patent Application No. 10-2024-0182400 filed Dec. 10, 2024, the entire disclosure of which is incorporated herein by reference.

### TECHNICAL FIELD

The technical spirit of the present disclosure relates to a semiconductor package and a method for transmitting and receiving data between chiplets, and more particularly, to a method for transmitting and receiving data between chiplets having different AXI parameters.

### BACKGROUND ART

In the semiconductor industry, advances in chiplet technology have enabled the integration of multiple dies within a single package. In this heterogeneous integration environment, the Advanced eXtensible Interface (hereinafter referred to as AXI) channel parameters used at the endpoints of each die may differ.

AXI protocol is a communication standard widely employed in system-on-chip (hereinafter referred to as SoC) designs, delivering high bandwidth and low latency. However, in a chiplet-based environment, during communication between dies having different AXI parameters, it becomes necessary to modulate AXI channel signals in accordance with each die's AXI channel configuration.

In chiplet technology, AXI parameters such as data bit-width are fixed at the design stage and are difficult to modify during the packaging process. While methods exist for parameter exchange between interconnected links within the chiplet network, such exchanges occur at the link layer (Die-to-Die Adapter). However, an end-to-end parameter exchange method at the protocol layer is required during packet exchange.

### PRIOR ART

### Patent Document

(Patent Document 0001) US 2022-0334995 A1 (Title: Parameter exchange for a die-to-die interconnect, Published: 2022.10.20)

### DETAILED DESCRIPTION OF THE INVENTION

### Technical Problem

The technical spirit of the present disclosure provides a method for exchanging parameters at the protocol layer during packet transmission and reception between chiplets.

The present disclosure provides a method for transmitting and receiving data between chiplets having different AXI parameters.

The present disclosure provides a method for preventing data loss during packet transmission and reception between chiplets through flow control.

However, the technical problem which the present disclosure intends to address is not limited to the problem mentioned above, and other problems not mentioned herein may be clearly understood on the basis of the following description.

### Technical Solution

According to the technical spirit of the present disclosure, a semiconductor package comprising a plurality of chiplets is provided, wherein each of the plurality of chiplets is configured to operate according to AXI protocol and the plurality of chiplets are configured to communicate with one another using Universal Chiplet Interconnect Express(hereinafter referred to as UCIe) protocol. A first chiplet of the plurality of chiplets comprises a first AXI interface configured to operate based on a first AXI parameter, and a first conversion module configured to receive a packet, extract a source AXI parameter from the received packet and convert the received packet into a target AXI signal based on the source AXI parameter and the first AXI parameter.

Alternatively, the source AXI parameter comprises one or more of write address (AW) channel bit-width, write data (W) channel bit-width, write response (B) channel bit-width, read address (AR) channel bit-width, read data (R) channel bit-width, address bit-width, transaction ID bit-width, write data bit-width, read data bit-width, and user data bit-width.

Alternatively, the first conversion module fills in the upper bit region of the address field of the target AXI signal with a predetermined value in response to the address bit-width of the source AXI parameter being smaller than the address bit-width of the first AXI parameter.

Alternatively, the first conversion module crops the upper bits of the address included in the received packet to align with the address field of the target AXI signal in response to the address bit-width of the source AXI parameter being greater than the address bit-width of the first AXI parameter.

Alternatively, the first conversion module merges a plurality of received packets to generate a target AXI signal in response to the bit-width of the write data or the read data of the source AXI parameter being smaller than the bit-width of the write data or the read data of the first AXI parameter.

Alternatively, the first conversion module splits a received packet to generate a plurality of target AXI signals in response to the bit-width of the write data or the read data of the source AXI parameter being greater than the bit-width of the write data or the read data of the first AXI parameter.

Alternatively, the packet is obtained by converting, according to UCIe protocol, an AXI channel signal generated according to AXI protocol.

Alternatively, the packet includes a packet header comprising one or more of write address (AW) channel bit-width, write data (W) channel bit-width, write response (B) channel bit-width, read address (AR) channel bit-width, read data (R) channel bit-width, address bit-width, transaction ID bit-width, write data bit-width, read data bit-width, and user data bit-width.

Alternatively, the packet header comprises a credit value indicating available reception buffer space in each of the plurality of chiplets; a second chiplet determines whether to transmit a packet based on buffer size to be occupied by the packet, and decreases the credit value upon transmission of the packet; a third chiplet, upon receiving the packet and generating a target AXI signal, sets a return credit value corresponding to the buffer size occupied by the packet and transmits the return credit to the second chiplet; and the second chiplet increases the credit value based on the return credit.

According to one embodiment of the present disclosure, a method, performed by a chiplet having a first AXI parameter, for transmitting and receiving data between chiplets having different AXI parameters comprises: receiving a packet; extracting a source AXI parameter from the received packet; and converting the received packet into a target AXI signal based on the source AXI parameter and the first AXI parameter. The packet is obtained by converting, according to UCIe protocol, an AXI channel signal generated according to AXI protocol.

Alternatively, converting the received packet into the target AXI signal comprises filling in the upper bit region of the address field of the target AXI signal with a predetermined value in response to the address bit-width of the source AXI parameter being smaller than the address bit-width of the first AXI parameter.

Alternatively, converting the received packet into the target AXI signal comprises cropping the upper bits of the address included in the received packet to align with the address field of the target AXI signal in response to the address bit-width of the source AXI parameter being greater than the address bit-width of the first AXI parameter.

Alternatively, converting the received packet into the target AXI signal comprises merging a plurality of received packets to generate a target AXI signal in response to the bit-width of the write data or the read data of the source AXI parameter being smaller than the bit-width of the write data or the read data of the first AXI parameter.

Alternatively, converting the received packet into the target AXI signal comprises splitting a received packet to generate a plurality of target AXI signals in response to the bit-width of the write data or the read data of the source AXI parameter being greater than the bit-width of the write data or the read data of the first AXI parameter.

### Advantageous Effects

According to the technical spirit of the present disclosure, it is possible to transmit and receive packets between chiplets having different AXI parameters, thereby increasing design flexibility in a chiplet-based environment.

The present disclosure enables buffer overflow at a receiver to be preemptively prevented by adding credit exchange information for flow control to the packet.

Effects attainable from the embodiments of the present disclosure are not limited to those described above, and other effects not mentioned herein may be clearly derived and understood by those having ordinary skill in the technical field to which the embodiments of the present disclosure pertain, based on the following description. That is, unintended effects arising from the implementation of the embodiments of the present disclosure may also be derived by those having ordinary skill in the technical filed based on the embodiments of the present disclosure.

### BRIEF DESCRIPTION OF THE DRAWINGS

FIG. 1 is a diagram illustrating a package structure comprising a plurality of chiplets.

FIG. 2 is a diagram illustrating a UCIe interconnect stack according to an exemplary embodiment of the present disclosure.

FIG. 3 is a diagram illustrating a method for generating a packet based on AXI channel signals according to an exemplary embodiment of the present disclosure.

FIG. 4 is a diagram illustrating a process for converting data using AXI parameters extracted from a packet according to an exemplary embodiment of the present disclosure,

FIG. 5 is a diagram illustrating a process for converting data using AXI parameters extracted from a packet according to an exemplary embodiment of the present disclosure.

FIG. 6 is a flowchart illustrating a method for generating AXI channel signals by receiving a packet generated by a chiplet having different AXI parameters according to an exemplary embodiment of the present disclosure.

### DETAILED DESCRIPTION OF THE EMBODIMENTS

Embodiments of the present disclosure are described in detail below with reference to the accompanying drawings so that those having ordinary skill in the technical field of the present disclosure (hereinafter referred to as those skilled in the art) can easily practice the present disclosure. The embodiments presented in the present disclosure are provided to enable those skilled in the art to use or practice the content of the present disclosure. Accordingly, various modifications to the embodiments of the present disclosure will be apparent to those skilled in the art. That is, the present disclosure may be implemented in various different forms and is not limited to the following embodiments.

The same or similar reference numerals denote the same or similar components throughout the description of the present disclosure. Additionally, in order to clearly describe the present disclosure, reference numerals for parts unrelated to the description of the present disclosure may be omitted in the drawings.

The term “or” used herein is intended not to mean an exclusive “or” but to mean an inclusive “or.” That is, unless otherwise specified herein or clearly indicated by the context, the clause “X uses A or B” should be understood to mean one of the natural inclusive substitutions. For example, unless otherwise specified herein or clearly indicated by the context, the clause “X uses A or B” may be interpreted as any one of a case where X uses A, a case where X uses B, and a case where X uses both A and B.

The term “and/or” used herein should be understood to refer to and include all possible combinations of one or more of listed related concepts.

The terms “comprise” and/or “comprising” used herein should be understood to mean that specific features and/or components are present. However, the terms “comprise” and/or “comprising” should be understood as not excluding the presence or addition of one or more other features, one or more other components, and/or combinations thereof.

Unless otherwise specified herein or unless the context clearly indicates a singular form, the singular form should generally be construed to include “one or more.”

The term “N-th (N is a natural number)” used herein may be understood as an expression used to distinguish the components of the present disclosure according to a predetermined criterion such as a functional perspective, a structural perspective, or the convenience of description. For example, in the present disclosure, components performing different functional roles may be distinguished as a first component or a second component. However, components that are substantially the same within the technical spirit of the present disclosure but should be distinguished for the convenience of description may also be distinguished as a first component or a second component.

As used herein, “chiplet” refers to a small modular semiconductor component designed to perform a specific function and configured to be combined with other chiplets to form a larger functional unit. A die refers to an individual integrated circuit chip cut from a semiconductor wafer, and a chiplet may be regarded as a form of die.

As used herein, “AXI” is a communication protocol developed by ARM, which may be used for data exchange between IPs within a SoC. AXI protocol comprises five channels, which may include AW (Write request), AR (Read request), W (Write data), R (Read data & response), and B (Write response) channels. Each channel has signals for channel data transmission, and also has Ready and Valid signals to confirm the data transfer. Data is considered successfully transferred when the transmitter's Valid signal and the receiver's Ready signal occur simultaneously. The bit-widths of each channel signal may be freely set and are determined as hardware parameters during the design stage.

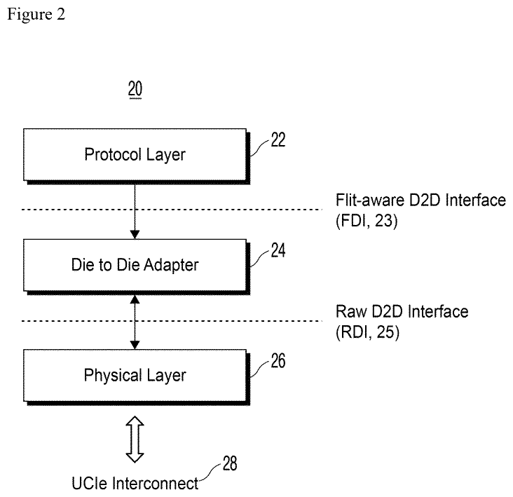

As used herein, “UCIe” is a protocol developed for data transmission between dies in a chiplet-based environment and may be used for transmitting packets or user-defined data conforming to PCIe or CXL standards. Referring to FIG. 2, the UCIe interconnect stack may comprise the protocol layer (22), the die-to-die adapter layer (24), and the physical layer (26). The protocol layer (22) manages and optimizes data communication between chiplets, including data packetization, flow control, error detection, and correction functions. The protocol layer (22) may support various protocols such as AXI, PCIe, and CXL. The die-to-die adapter layer (24) may have logic to add additional information to packets generated by the protocol layer (22) and ensure delivery of such packets to other chiplets'die-to-die adapter layers. The physical layer (26) may comprise physical or electrical components for data communication. For example, the physical layer (26) may handle packet transmission via electrical signals over physical connections between dies (or chiplets)

Hereinafter, embodiments of the present disclosure are described in detail with reference to the accompanying drawings.

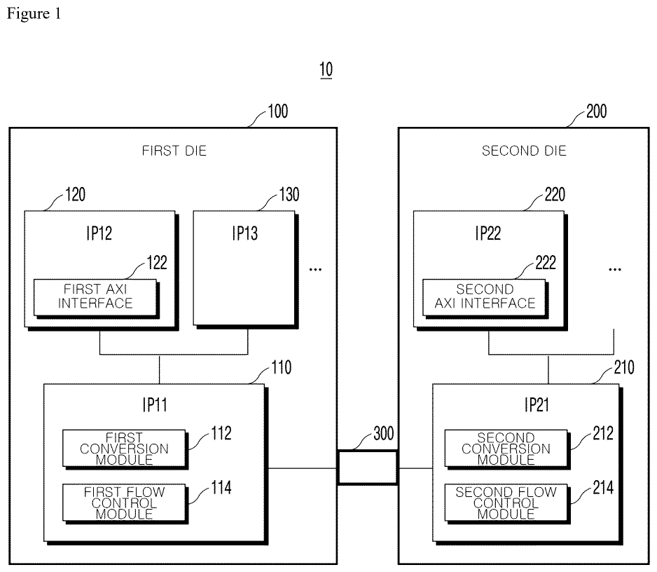

FIG. 1 is a diagram illustrating a package structure comprising a plurality of chiplets.

Referring to FIG. 1, the semiconductor package (10) may comprise the first chiplet (100), the second chiplet (200), and the channel (300) connecting the first chiplet (100) and the second chiplet (200). The semiconductor package (10) may further comprise a plurality of chiplets.

The first chiplet (100) may comprise a plurality of Intellectual Property (hereinafter referred to as IP) blocks. The first chiplet (100) may comprise IP11 (110), IP12 (120), and IP13 (130). IP11 (110) may comprise the first conversion module (112), the first flow control module (114), and the first AXI interface (122). The configurations included in IP11 (110) are distinguished for convenience of description and may be differently distinguished or may include additional circuits for various functions. For example, the first conversion module (112) and the first flow control module (114) may be included in the receiver, and the first AXI interface (122) may be included in a separate interface IP block.

Alternatively, IP11 (110) may include a receiver (not shown) or a transmitter (not shown). The receiver may receive, analyze, and process packets from other chiplets. The receiver may restore the received packets into AXI channel signals through a de-packetization process. The receiver may modulate the received AXI channel signals according to the AXI parameters of its chiplet. The transmitter may transmit packets to other chiplets. The transmitter may packetize AXI channel parameters and signals for transmission. The transmitter may provide an interface for high-speed data transmission between chiplets. A plurality of IP blocks may include receiver IPs, transmitter IPs, as well as processor IPs, interface IPs, foundation IPs, and various other types of IP blocks.

The first conversion module (112) may extract a source AXI parameter from a received packet and convert the received packet into a target AXI signal based on the source AXI parameter and the first AXI parameter. The source AXI parameter may correspond to the AXI parameter of the second chiplet (200) or the second AXI interface (222). The first AXI parameter may correspond to the AXI parameter of the first chiplet (100) or the first AXI interface (122). The received packet may be generated by the second chiplet (200). The target AXI signal may be an AXI channel signal used by the first chiplet (100) or the first AXI interface (122). The packet may be obtained by converting, according to UCIe protocol, an AXI channel signal generated according to AXI protocol.

The source AXI parameter may comprise one or more of a write address (AW) channel bit-width, a write data (W) channel bit-width, a write response (B) channel bit-width, a read address (AR) channel bit-width, a read data (R) channel bit-width, an address bit-width, a transaction ID bit-width, a write data bit-width, a read data bit-width, or a user data bit-width.

The second chiplet (200) may comprise IP21 (210) and IP22 (220). IP21 (210) may comprise the second conversion module (212), the second flow control module (214), and the second AXI interface (222).

In UCIe specification, the receiver has no means to block packet data sent by the transmitter, potentially resulting in data loss due to buffer overflow at the receiver. Therefore, credit exchange information related to flow control is added to packets to prevent buffer overflow phenomena at the receiver in advance.

The first flow control module (114) and the second flow control module (214) may control credit values contained in packets for flow control.

The second flow control module (214, or the second chiplet) determines whether to transmit a packet based on the buffer size occupied by the packet and may decrease the credit value upon transmission of the packet. The first flow control module (114, or a third chiplet), upon receiving the packet and generating the target AXI signal, may set a return credit value corresponding to the buffer size occupied by the packet and transmit the return credit to the second chiplet. The second chiplet may increase the credit value based on the return credit. If the credit value is insufficient, the second flow control module (214, or the second chiplet) may determine that the buffer of the third chiplet is full and stop transmitting packets.

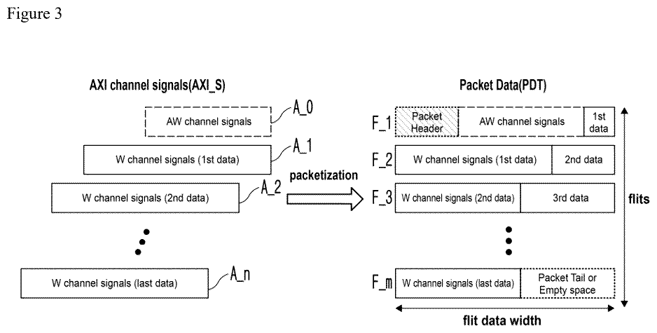

FIG. 3 is a diagram illustrating a method for generating a packet based on AXI channel signals according to an exemplary embodiment of the present disclosure.

Referring to FIG. 3, a chiplet may generate the packet (PDT) based on the AXI channel signals (AXI_S) for communication between chiplets. The AXI channel signals (AXI_S) may comprise the AW (Write Address) channel signal (A_0) and the n W (Write Data) channel signals. For example, one write transaction may generate the AW channel signal (A_0) containing transaction details and at least one of the W channel signals (A_1, . . . , A_n) containing data necessary for the transaction.

In the UCIe protocol layer, the generated AW channel signal (A_0) and W channel signals (A_1, . . . , A_n) may be used to create the packet (PDT), which may be transmitted according to the data width of the UCIe link. At this time, additional information about the data contained in the packet (PDT) may be included in a packet header located at the front of the packet. A Flit (Flow Control Unit) is the basic unit of data transfer in UCIe, and its size may be determined through negotiation between chiplets.

The packet header may comprise AXI parameters such as transaction ID bit-width, write data bit-width, read data bit-width, or user data bit-width. The packet header may comprise a write address (AW) channel bit-width, a write data (W) channel bit-width, a write response (B) channel bit-width, a read address (AR) channel bit-width, a read data (R) channel bit-width. The packet header may also comprise flit size information, error detection, correction codes, address information, transaction IDs, packet type, sequence numbers, and protocol identifiers.

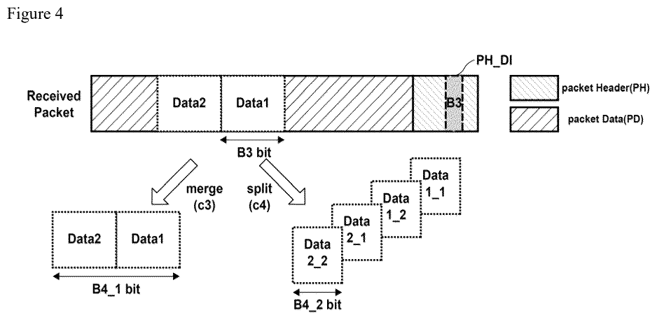

FIG. 4 is a diagram illustrating a process for converting data using AXI parameters extracted from a packet according to an exemplary embodiment of the present disclosure.

Referring to FIG. 4, among a plurality of chiplets, a first chiplet (or conversion module) may receive a packet transmitted from a second chiplet, thereafter extract detailed information (or AXI parameters) of AXI channel signals contained in the packet header (PH). The first chiplet and the second chiplet may have different AXI parameters. The packet may comprise the packet header (PH) and the packet data (PD). The packet header (PH) may include the address bit-width information (PH_AI). The first chiplet may convert the data according to the first chiplet using the address bit-width information (PH_AI) included in the received packet.

For example, if the address bit-width (B1) included in the packet transmitted from the second chiplet is 48 bits, the first chiplet may identify that the length (B1) of the address data (AD1) in the packet data (PD) is 48 bits and extract the address data (AD1) according to the length (B1). The first chiplet may compare the address bit-width (B1) of the packet from the second chiplet with the address bit-width used in its AXI channel.

When the first chiplet's address bit-width (B2_1) is greater than the second chiplet's address bit-width (B1), the first chiplet may put the received address data (AD1) into the address data (AD2_1) and fill in any empty upper bit region (AD_OS) with a predetermined value. For example, if the first chiplet's address bit-width (B2_1) is 64 bits, the upper 16 bits may be filled in with a predetermined value, which may be set using the Control and Status Register (hereinafter referred to as CSR) of the first chiplet.

When the first chiplet's address bit-width (B2_2) is smaller than the second chiplet's address bit-width (B1), the first chiplet may crop the upper bit region (CR) of the address data (AD1) included in the received packet.

The algorithm described in FIG. 4 may be applied to write address(AW), write response(B), and read address(AR) channels.

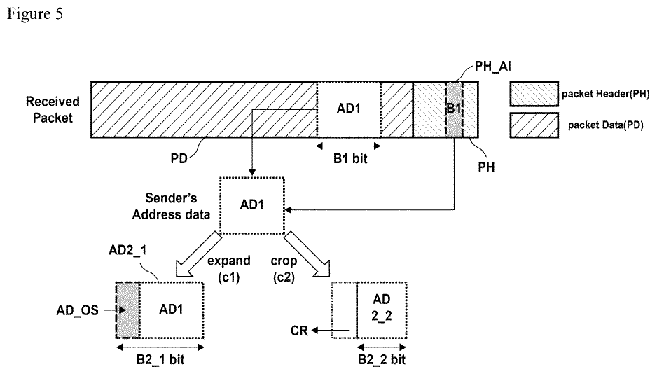

FIG. 5 is a diagram illustrating a process for converting data using AXI parameters extracted from a packet according to an exemplary embodiment of the present disclosure.

Referring to FIG. 5, among a plurality of chiplets, a first chiplet (or conversion module) may receive a packet transmitted from a second chiplet, thereafter extract detailed information (or AXI parameters) of AXI channel signals contained in the packet header (PH). The first chiplet and the second chiplet may have different AXI parameters. The packet may comprise the packet header (PH) and the packet data (PD). The packet header (PH) may include the data bit-width information (PH_DI). The first chiplet may convert the data according to the first chiplet using the data bit-width information (PH_DI) included in the received packet.

For example, if the data bit-width (B3) included in the packet transmitted from the second chiplet is 64 bits, the first chiplet may identify that the length (B3) of the data (Data1) in the packet data (PD) is 64 bits and extract the data (Data1) according to the length (B3). The first chiplet may compare the data bit-width (B3) of the packet from the second chiplet with the data bit-width used in its the AXI channel.

When the first chiplet's data bit-width (B4_1) is greater than the second chiplet's data bit-width (B3), for example, when the first chiplet's data bit-width (B4_1) is 128 bits, the first chiplet may merge the plurality of received data (Data1, Data2).

When the first chiplet's data bit-width (B4_2) is smaller than the second chiplet's data bit-width (B3), for example, when the first chiplet's data bit-width (B4_2) is 32 bits, the first chiplet may split the received data (Data1, Data2) into the plurality of data (Data1_1, Data1_2, Data2_1, Data2_2) according to the data bit-width (B4_2).

The algorithm described in FIG. 5 may be applied to write data (W) and read data (R) channels.

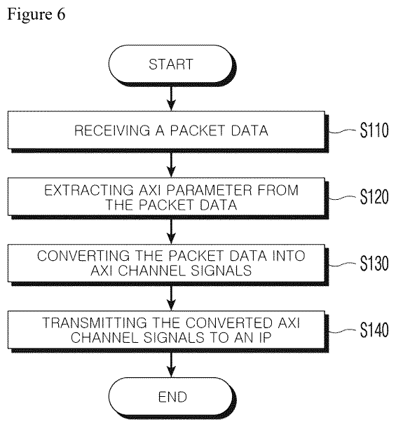

FIG. 6 is a flowchart illustrating a method for generating AXI channel signals by receiving a packet generated by a chiplet having different AXI parameters according to an exemplary embodiment of the present disclosure.

Referring to FIG. 6, a first chiplet may receive a packet (S110). For example, a second chiplet may generate and transmit a packet based on the AXI channel parameters and AXI channel signals of the transmitter. The receiver of the first chiplet may receive the packet transmitted from the second chiplet.

The first chiplet may extract a source AXI parameter from the received packet (S120). For example, the receiver of the first chiplet may de-packetize the received packet and extract the source AXI parameter (or the AXI parameter of the second chiplet).

The first chiplet may convert packet data into AXI channel signals (S130). Based on the extracted source AXI parameter and the AXI parameter of the first chiplet, the first chiplet may modulate the AXI channel signals in accordance with the AXI parameters of the first chiplet's receiver.

The first chiplet may transmit the converted AXI channel signals to an IP (S140). The first chiplet may deliver the converted AXI channel signals to the end-point of the die.

A packet may include AXI parameter information in its packet header and AXI signals may be restored and converted dynamically with only packet data without end-to-end parameter exchange at the protocol layer. The present invention enables AXI communication between chiplets having different AXI parameters in an environment where each die's AXI parameter is fixed on hardware and cannot be changed. The present invention enables multiple AXI channel signals having different AXI parameters to share a single UCIe link.

The various embodiments of the present disclosure described above may be combined with additional embodiments and may be modified within a range understandable to those skilled in the art based on the foregoing detailed description. The embodiments of the present disclosure are to be understood as illustrative in all respects and not limiting. For example, individual components described as being implemented in a unitary form may be implemented in a distributed manner, and likewise, components described as being implemented in a distributed manner may be implemented in a combined form. Therefore, all changes or modifications derived from the meaning, scope, and equivalents of the claims of the present disclosure are to be construed as being included within the scope of the present disclosure.

1. A semiconductor package comprising a plurality of chiplets, wherein:
each of the plurality of chiplets is configured to operate according to AXI protocol;
the plurality of chiplets are configured to communicate with one another using UCIe protocol; and
a first chiplet of the plurality of chiplets comprises:
a first AXI interface configured to operate based on a first AXI parameter; and
a first conversion module configured to receive a packet, extract a source AXI parameter from the received packet, and convert the received packet into a target AXI signal based on the source AXI parameter and the first AXI parameter.

2. The semiconductor package of claim 1, wherein
the source AXI parameter comprises one or more of write address (AW) channel bit-width, write data (W) channel bit-width, write response (B) channel bit-width, read address (AR) channel bit-width, read data (R) channel bit-width, address bit-width, transaction ID bit-width, write data bit-width, read data bit-width, and user data bit-width.

3. The semiconductor package of claim 2, wherein
the first conversion module fills in the upper bit region of the address field of the target AXI signal with a predetermined value in response to the address bit-width of the source AXI parameter being smaller than the address bit-width of the first AXI parameter.

4. The semiconductor package of claim 2, wherein
the first conversion module crops the upper bits of the address included in the received packet to align with the address field of the target AXI signal in response to the address bit-width of the source AXI parameter being greater than the address bit-width of the first AXI parameter.

5. The semiconductor package of claim 2, wherein
the first conversion module merges a plurality of received packets to generate a target AXI signal in response to the bit-width of the write data or the read data of the source AXI parameter being smaller than the bit-width of the write data or the read data of the first AXI parameter.

6. The semiconductor package of claim 2, wherein
the first conversion module splits a received packet to generate a plurality of target AXI signals in response to the bit-width of the write data or the read data of the source AXI parameter being greater than the bit-width of the write data or the read data of the first AXI parameter.

7. The semiconductor package of claim 1, wherein
the packet is obtained by converting, according to UCIe protocol, an AXI channel signal generated according to AXI protocol.

8. The semiconductor package of claim 1, wherein
the packet includes a packet header comprising one or more of write address (AW) channel bit-width, write data (W) channel bit-width, write response (B) channel bit-width, read address (AR) channel bit-width, read data (R) channel bit-width, address bit-width, transaction ID bit-width, write data bit-width, read data bit-width, and user data bit-width.

9. The semiconductor package of claim 8, wherein
the packet header comprises a credit value indicating available reception buffer space in each of the plurality of chiplets;
the second chiplet determines whether to transmit a packet based on buffer size to be occupied by the packet, and decreases the credit value upon transmission of the packet;
the third chiplet, upon receiving the packet and generating a target AXI signal, sets a return credit value corresponding to the buffer size occupied by the packet and transmits the return credit to the second chiplet;
and the second chiplet increases the credit value based on the return credit.

10. A method, performed by a chiplet having a first AXI parameter, for transmitting and receiving data between chiplets having different AXI parameters, the method comprising:
receiving a packet;
extracting a source AXI parameter from the received packet; and
converting the received packet into a target AXI signal based on the source AXI parameter and the first AXI parameter,
wherein the packet is obtained by converting, according to UCIe protocol, an AXI channel signal generated according to AXI protocol.

11. The method of claim 10, wherein
converting the received packet into a target AXI signal comprises
filling in the upper bit region of the address field of the target AXI signal with a predetermined value in response to the address bit-width of the source AXI parameter being smaller than the address bit-width of the first AXI parameter.

12. The method of claim 10, wherein
converting the received packet into a target AXI signal comprises
cropping the upper bits of the address included in the received packet to align with the address field of the target AXI signal in response to the address bit-width of the source AXI parameter being greater than the address bit-width of the first AXI parameter.

13. The method of claim 10, wherein
converting the received packet into a target AXI signal comprises
merging a plurality of received packets to generate a target AXI signal in response to the bit-width of the write data or the read data of the source AXI parameter being smaller than the bit-width of the write data or the read data of the first AXI parameter.

14. The method of claim 10, wherein
converting the received packet into a target AXI signal comprises
splitting a received packet to generate a plurality of target AXI signals in response to the bit-width of the write data or the read data of the source AXI parameter being greater than the bit-width of the write data or the read data of the first AXI parameter.
